(19) United States
(12) Patent Application Publication
(10) Pub. No.: US 2012/0056318 A1
(43) Pub. Date: Mar. 8, 2012

(54) SEMICONDUCTOR DEVICE

(76) Inventor: Masaharu SETO, Kanagawa (JP)

(21) Appl. No.: 13/049,383

(22) Filed: Mar. 16, 2011

(30) Foreign Application Priority Data
Sep. 3, 2010 (JP) 2010-198385

(51) Int. Cl. H01L 23/485

(52) U.S. Cl. 257/737; 257/E23.021

(57) ABSTRACT

According to one embodiment, there is provided a semiconductor device including a semiconductor element, an electrode pad of the semiconductor element, a buffer coat film, and a micro-bump. The buffer coat film has an opening corresponding to the electrode pad. The micro-bump is electrically connected to the electrode pad through the opening. A contact area between the micro-bump and side surfaces of the opening is larger than a contact area between the micro-bump and a bottom surface of the opening.

### CROSS-REFERENCE TO RELATED APPLICATIONS

This application is based upon and claims the benefit of priority from the prior Japanese Patent Application No. 2010-198385, filed on Sep. 3, 2010; the entire contents of all of which are incorporated herein by reference.

### FIELD

Embodiments described herein relate generally to a semiconductor device.

### BACKGROUND

In regard with a process of manufacturing a semiconductor device, a method has been employed, in which in order to reduce the thickness of a semiconductor substrate, back-grinding is performed in a state in which micro-bumps are attached to the electrode pad of a semiconductor element on a semiconductor substrate through opening of a buffer coat film, and an adhesive sheet is bonded to the surfaces of the micro-bumps opposite to the surfaces attached to the electrode pad. In this case, if the adhesion between the micro-bumps and the electrode pad is weaker than the adhesion between the micro-bumps and the adhesive sheet, micro-bumps are likely to be detached from the electrode pad when the adhesive sheet is removed after the completion of the back-grinding. Since the contact area between the micro-bump and the electrode pad decreases with the progress of shrinkage in the diameter of the micro-bump, there is a concern that the adhering force of the micro-bumps to the semiconductor element may decrease.

### BRIEF DESCRIPTION OF THE DRAWINGS

FIGS. 1A and 1B are diagrams showing a configuration of a semiconductor device according to a first embodiment;

FIGS. 2A and 2B are diagrams showing a configuration of a semiconductor device according to a modification of the first embodiment;

FIG. 3 is a diagram showing a configuration of a semiconductor device according to another modification of the first embodiment;

FIG. 4 is a diagram showing a configuration of a semiconductor device according to a second embodiment;

FIGS. 5A and 5B are diagrams showing a method for manufacturing the semiconductor device according to the second embodiment;

FIGS. 6A to 6C are diagrams showing a method for manufacturing the semiconductor device according to the second embodiment; and

FIGS. 7A to 7C are diagrams showing a method for manufacturing the semiconductor device according to the second embodiment.

### DETAILED DESCRIPTION

In general, according to one embodiment, there is provided a semiconductor device including a semiconductor element, an electrode pad of the semiconductor element, a buffer coat film, and a micro-bump. The buffer coat film has an opening corresponding to the electrode pad. The micro-bump is electrically connected to the electrode pad through the opening. A contact area between the micro-bump and side surfaces of the opening is larger than a contact area between the micro-bump and a bottom surface of the opening.

In this specification, the expression “a first layer is formed on a second layer” includes a case where the first layer is formed directly on the second layer and also includes a case where the first layer is formed on the second layer with a third layer disposed therebetween.

Exemplary embodiments of a semiconductor device will be explained below in detail with reference to the accompanying drawings. The present invention is not limited to the following embodiments.

### First Embodiment

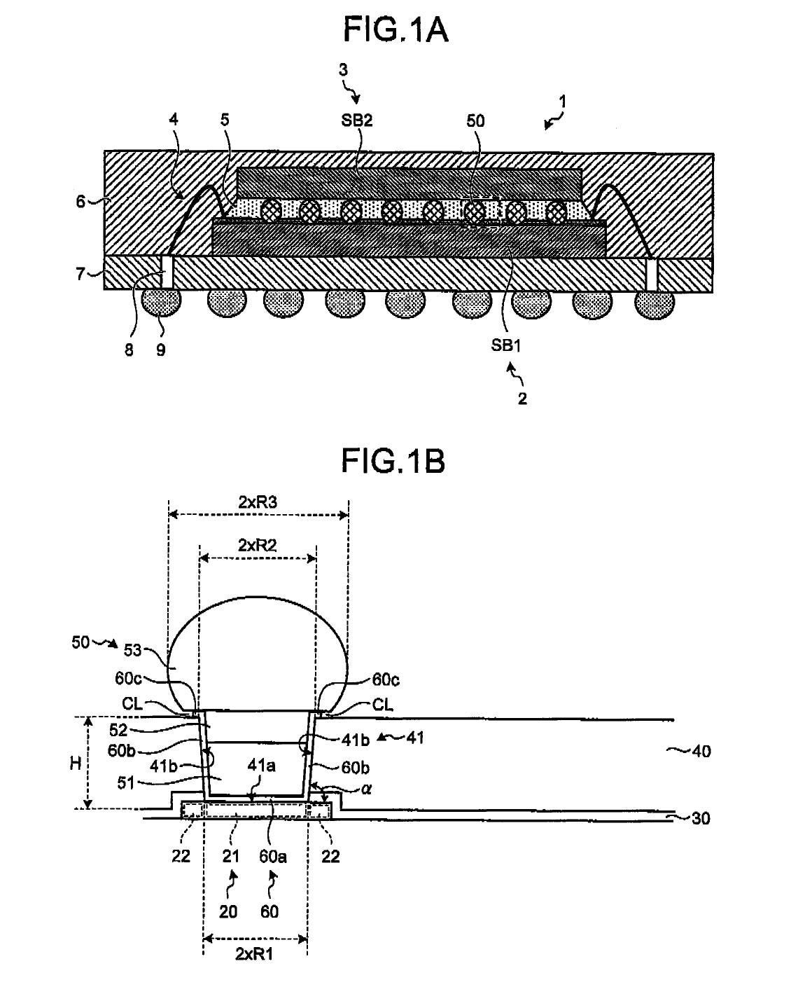

A schematic configuration of a semiconductor device 1 according to a first embodiment will be described with reference to FIG. 1A. FIG. 1A is a diagram showing a schematic configuration of the semiconductor device 1.

The semiconductor device 1 includes a semiconductor element 2, a semiconductor element 3, a plurality of bonding wires 4, sealing resin portions 5 and 6, a board 7, a plurality of conductor posts 8, a plurality of conductor balls 9, and a plurality of micro-bumps 50.

The semiconductor element 2 is a structure in which a predetermined circuit is formed on a semiconductor substrate SB1. The semiconductor element 2 is, for example, a memory chip in which a predetermined memory circuit (for example, a DRAM) is formed on the semiconductor substrate SB1.

The semiconductor element 3 is a structure in which a predetermined circuit is formed on a semiconductor substrate SB2. The semiconductor element 3 is, for example, a logic chip in which a predetermined logic circuit (for example, an ASIC) is formed on the semiconductor substrate SB2. The surface of the semiconductor element 3, on which the predetermined circuit is formed, faces the surface of the semiconductor element 2, on which the predetermined circuit is formed.

The plurality of bonding wires 4 electrically connect the electrode pad (not shown) of the semiconductor elements 2 and 3 to the conductor posts 8 so as to allow inputting and outputting of a predetermined signal to and from the semiconductor elements 2 and 3. The bonding wires 4 are formed, for example, of gold.

The sealing resin portion 5 enables resin-sealing of a space between the semiconductor elements 2 and 3 and the plurality of micro-bumps 50. The sealing resin portion 6 enables resin-sealing of the semiconductor elements 2 and 3, the sealing resin portion 5, and the bonding wires 4. The sealing resin portions 5 and 6 are formed, for example, of a molding resin.

The board 7 has the semiconductor elements 2 and 3 which are stacked and mounted thereon. The conductor posts 8 pass through the board 7.

The plurality of conductor posts 8 pass through the board 7, and one ends thereof are connected, to the bonding wires 4 and the other ends are connected to the conductor balls 9. The conductor posts B are formed, for example, of copper.

The plurality of conductor balls 9 are arranged on the surface of the board 7 opposite to the surface where the semiconductor element 2 or 3 is mounted. The conductor balls 9 are connected to the conductor posts 8. The plurality of conductor balls 9 function as input or output terminals for allowing the semiconductor device 1 to receive or send signals from or to an external device.

The plurality of micro-bumps 50 electrically connect electrode pads (for example, an electrode pad 20 shown in FIG. 13) of the semiconductor element 2 to electrode pads (not shown) of the semiconductor element 3. In this way, the plurality of micro-bumps 50 function as input or output terminals for allowing the semiconductor element 2 to receive or send signals from or to the semiconductor element 3.

Next, a configuration of the semiconductor device 1 in the vicinity of the micro-bumps 50 will be described with reference to FIG. 13. FIG. 15 is a diagram showing a configuration of the semiconductor device 1 in the vicinity of the micro-bumps 50. In the following description, the configuration in the vicinity of the micro-bumps 50 on the semiconductor element 2 will be described as an example. However, similar description can be applied to the configuration in the vicinity of the micro-bumps 50 on the semiconductor element 3.

The semiconductor device 1 includes the electrode pad 20, a passivation film 30, a buffer coat film 40, a conducting layer 60, and the micro-bumps 50.

The electrode pad 20 are formed on the semiconductor element 2 and function as electrodes for allowing the semiconductor element 2 to send or receive a predetermined signal. The electrode pad 20 are formed of a conductor, and specifically, are formed of a metal containing aluminum as its main component.

Each electrode pad 20 has a central portion 21 and a peripheral portion 22. The central portion 21 is a portion including the center of the electrode pad 20. The peripheral portion 22 is a portion disposed around the central portion 21 of each electrode pad 20.

The passivation film 30 covers the peripheral portion 22 of the electrode pad 20 and the semiconductor element 2. In this way, the passivation film 30 protects the peripheral portion 22 of the electrode pad 20 and the semiconductor element 2. The passivation film 30 has a two-layer structure made up of a silicon oxide film and a silicon nitride film, for example, and the front surface thereof may be formed of a silicon nitride film, for example. Moreover, the passivation film 30 has an opening that exposes the central portions 21 of the electrode pad 20.

The buffer coat film 40 covers the peripheral portion 22 of the electrode pad 20, the semiconductor element 2, and the passivation film 30. The buffer coat film 40 is formed, for example, of a phenolic resin or a polyimide resin.

Moreover, the buffer coat film 40 has an opening 41 that exposes the central portions 21 of the electrode pad 20. The opening 41 of the buffer coat film 40 are configured to correspond to the opening of the passivation film 30 (for example, the two kinds of openings are in alignment). In the following description, to simplify the description, the opening 41 of the buffer coat film 40 and the opening of the passivation film 30 will be simply referred to as opening 41.

The conducting layer 60 covers a bottom surface 41a and side surfaces 41b of the opening 41 and also covers end portions of the surface of the buffer coat film 40 being in contact with the opening 41. That is, the conducting layer 60 includes a bottom surface portion 60a, side surface portions 60b, and end portions 60c. The bottom surface portion 60a covers the bottom surface 41a of the opening 41 and connects the bottom surface 41a (the central portion 21 of the electrode pad 20) of the opening 41 to the bottom surface of the micro-bump 50. The side surface portions 60b cover the side surfaces 41b of the opening 41 and connect the side surfaces of the lower part of the micro-bump 50 to the side surfaces 41b (the buffer coat film 40) of the opening 41. The end portions 60c cover the end portions on the surface of the buffer coat film 40 being in contact with the opening 41 and connect the lower end of the upper part of the micro-bump 50 to the buffer coat film 40. A clearance CL disposed between the lower end of the upper part of the micro-bump 50 and the surface of the buffer coat film 40 is formed on the outer side of the end portions 60c. The conducting layer 60 is formed, for example, of a sputtering film made up of a titanium metal layer and a copper metal layer.

The micro-bump 50 is made up of three layers 51, 52, and 53. In the micro-bump 50, these layers 51, 52, and 53 are sequentially stacked. For example, the layers 51 and 52 constitute the lower part of the micro-bump 50, and the layer 53 constitutes the upper part of the micro-bump 50. The layer 51 covers the bottom surface 41a of the opening 41. The layer 51 is formed, for example, of a metal containing nickel as its main component. The layer 52 covers the layer 51. The layer 52 is formed, for example, of a metal containing copper as its main component. The layer 53 covers the surfaces of the layer 52 and the buffer coat film 40 in the vicinity of the opening 41. The layer 53 is formed, for example, of metal (for example, SnCu, SnAg, and SnAgCu) containing tin as its main component.

Moreover, the micro-bump 50 has the lower part (the layers 51 and 52) which is buried in the opening 41. The micro-bump 50 is in contact with the bottom surface 41a and the side surfaces 41b of the opening 41 through the conducting layer 60. In this way, the micro-bump 50 is electrically connected to the electrode pad 20 through the opening 41. That is, the bottom surface of the micro-bump 50 is in contact with the bottom surface 41a of the opening 41 through the bottom surface portion 60a. The side surfaces of the lower part of the micro-bump 50 are in contact with the side surfaces 41b of the opening 41 through the side surface portions 60b. The lower end of the upper part of the micro-bump 50 is in contact with the end portions of the surface of the buffer coat film 40 being in contact with the opening 41 through the end portions 60c.

As shown in FIG. 1B, a contact area ‘Sb’ between the micro-bump 50 and the side surfaces 41b of the opening 41 is larger than a contact area ‘Sa’ between the micro-bump 50 and the bottom surface 41a of the opening 41. Moreover, as shown in FIG. 1B, the opening 41 has a forward-tapered shape in which the width (2×R2) of the upper part is larger than the width (2×R1) of the bottom surface. That is, the taper angle α of the side surface 41b of the opening 41 with'respect to the surface of the peripheral portion 22 covered by the buffer coat film 40 is equal to or larger than 80°.

Specifically, when the taper angle α (≧80°) of the side surface 41b of the opening 41 is approximated to 90°, and if the depth (≈‘the height of the lower part of the micro-bump 50’) of the opening 41 is H, and the diameter (≈‘the diameter of the bottom surface of the micro-bump 50’) is 2×R1, the contact areas can be expressed as follows.

Sa=π(R1)²

Sb=2πR1H

Thus, the following expression is obtained.

Sb>Sa

2πR1H>π(R1)²

2H>R1 Expression 1

For example, if the diameter (≈‘the diameter of the bottom surface of the micro-bump 50’) of the bottom surface 41a of the opening 41 is 2×R1=10 μm, namely R1=5 μm, then Expression 1 can be written as follows.

H>2.5 Expression 2

In this case, if H=2.6 μm, the other values shown in FIG. 1B are calculated as α=80°, 2×R2=10.0 μm, and 2×R3=12 μm, for example.

The present inventor conducted a test in which shear stress is applied to the micro-bump 50 along the surface of the electrode pad 20 with respect to various values of the depth of the opening 41 when the diameter of the bottom surface of the micro-bump 50 is 10 μm. According to the test results, under the conditions where the depth of the opening 41 is out of the range of Expression 2, that is, where the depth is smaller than 2.5 μm, the micro-bump 50 was removed from the electrode pad under shear stress equal to or smaller than 40 mN. In contrast, under the conditions where the depth of the opening 41 is within the range of Expression 2, that is, the depth is larger than 2.5 μm, the micro-bump 50 was removed from the electrode pad under shear stress equal to or larger than 70 mN.

Considering the fact that adhesion force of an adhesive sheet used for back-grinding is 60±10 mN, it was ascertained that the micro-bump 50 needs to be in contact with the bottom surface 41a and the side surfaces 41b of the opening 41 within the range of Expression 2 in order to prevent the micro-bump from being removed from the electrode pad when the adhesive sheet is removed after the back-grinding.

The present inventor also conducted similar test to above one with respect to various values of the depth of the opening 41 when considering the fact that a dimensional fluctuation (on one side) which is expected during manufacturing of the micro-bump 50 is 2.5 μm, the diameter of the bottom surface of the micro-bump 50 is 10 μm-2.5 μm×2=5 μm.

According to the test results, under the conditions where the depth of the opening 41 is out of the range of

H>5 Expression 3,

that is, where the depth is smaller than 5 μm, the micro-bump 50 was removed from the electrode pad under shear stress equal to or smaller than 40 mN. In contrast, under the conditions where the depth of the opening 41 is within the range of Expression 3, that is, the depth is larger than 5 μm, the micro-bump 50 was removed from the electrode pad under shear stress equal to or larger than 70 mN.

Considering the fact that a dimensional fluctuation (on one side) which is expected during manufacturing of the micro-bump 50 is 2.5 μm as well as the fact that adhesion force of an adhesive sheet used for back-grinding is 60±10 mN, it was ascertained that the micro-bump 50 needs to be in contact with the bottom surface 41a and the side surfaces 41b of the opening 41 within the range of Expression 3 in order to prevent the micro-bump from being removed from the electrode pad when the adhesive sheet is removed after the back-grinding.

Since the condition of Expression 3 can be normalized by substituting R1 in Expression 1 with R1/2, the following expression is obtained.

2H>R1/2

2πR1H>2×π(R1)²

Sb>2×Sa Expression 4

That is, when the dimensional fluctuation expected during manufacturing of the micro-bump 50 is also taken into consideration, it is preferable that the contact area ‘Sb’ between the micro-bump 50 and the side surfaces 41b of the opening 41 is larger than twice the contact area ‘Sa’ between the micro-bump 50 and the bottom surface 41a of the opening 41.

When the diameter (≈‘the diameter of the bottom surface of the micro-bump 50’) is 2×R1=14 μm, from Expression 1, the condition of Sb>Sa can be written as follows.

H>3.5 Expression 5

In this case, if H=3.6 μm, the other values shown in FIG. 1B are calculated as α=80°, 2×R2=15.3 μm, and 2×R3=20 μm, for example.

Moreover, from Expression 4, the condition of Sb>2×Sa can be written as follows.

H>7 Expression 6

Here, a case in which the contact area ‘Sb’ between the micro-bump 50 and the side surfaces 41b of the opening 41 is smaller than the contact area ‘Sa’ between the micro-bump 50 and the bottom surface 41a of the opening 41 will be considered. In this case, since the contact area between the micro-bump 50 and the electrode pad 20 decreases as the diameter of the micro-bump 50 is shrunk, the force of attaching the micro-bump 50 to the electrode pad 20 is likely to be smaller than the adhesion force of the micro-bump 50 by the adhesive sheet. Thus, the micro-bump 50 can be easily removed from the electrode pad 20 when the adhesive sheet is removed after the back-grinding. That is, the force of attaching the micro-bump 50 to the semiconductor element 2 is likely to decrease.

In contrast, in the first embodiment, the contact area ‘Sb’ between the micro-bump 50 and the side surfaces 41b of the opening 41 is larger than the contact area ‘Sa’ between the micro-bump 50 and the bottom surface 41a of the opening 41. With this configuration, the contact area between the micro-bump 50 and the buffer coat film 40 becomes larger than the contact area between the micro-bump 50 and the electrode pad 20. Accordingly, even when the contact area between the micro-bump 50 and the electrode pad 20 decreases as the diameter of the micro-bump 50 is shrunk, it is possible to secure the force of closely attaching the micro-bump 50 to the buffer coat film 40. As a result, it is possible to improve the force of attaching the micro-bump 50 to the semiconductor element 2.

In particular, in the first embodiment, the contact area ‘Sb’ between the micro-bump 50 and the side surfaces 41b of the opening 41 is larger than twice the contact area ‘Sa’ between the micro-bump 50 and the bottom surface 41a of the opening 41. With this configuration, even when the dimensions of the micro-bump 50 fluctuate during manufacturing as described above, since it is possible to secure the force of closely attaching the micro-bump 50 to the buffer coat film 40, it is possible to improve the force of attaching the micro-bump 50 to the semiconductor element 2.

Moreover, in the first embodiment, the taper angle α of the side surface 41b of the opening 41 with respect to the surface of the peripheral portion 22 covered by the buffer coat film 40 is equal to or larger than 80°. With this configuration, even when the diameter of the micro-bump 50 is shrunk, the contact area between the micro-bump 50 and the buffer coat film 40 can be easily made larger than the contact area between the micro-bump 50 and the electrode pad 20. Moreover, even when the diameter of the micro-bump 50 is shrunk, it is possible to prevent the micro-bump 50 from being tilted in the process of manufacturing the semiconductor device 1.

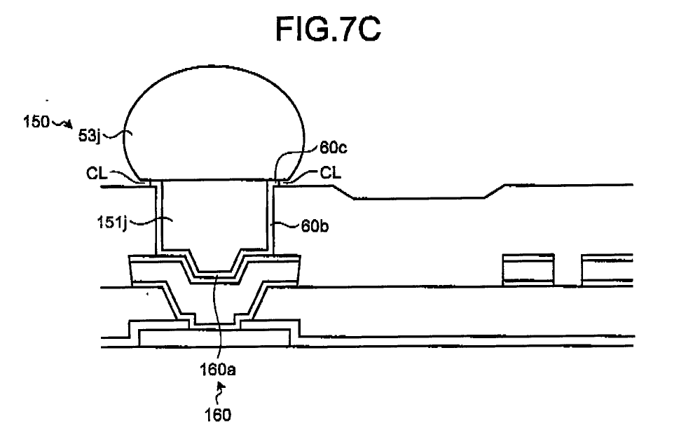

Moreover, in the first embodiment, decreased is the volume ratio of the exposed portion of the conducting layer 60 to the portion of the conducting layer 60 being in contact with the micro-bump 50, the electrode pad 20, and the buffer coat film 40. With this configuration, the conducting layer 60 has a structure suitable for decreasing the effect of side-etching on the conducting layer 60 when etching is performed so as to form the conducting layer 60 (see FIGS. 7B and 7C).

It should be noted that the passivation film 30 and the buffer coat film 40 may have an opening that exposes the peripheral portion 22 as well as the central portion 21 of the electrode pad 20. In this case, the conducting layer 60 covers the central portion 21 and the peripheral portion 22 of the electrode pad 20, which serve as the bottom surface of the opening. The micro-bump 50 is connected to the central portion 21 and the peripheral portion 22 of the electrode pad 20 through the opening.

Moreover, the semiconductor device 1 may have a structure that does not have the conducting layer 60 between the micro-bump 50 and each of the electrode pad 20 and buffer coat film 40.

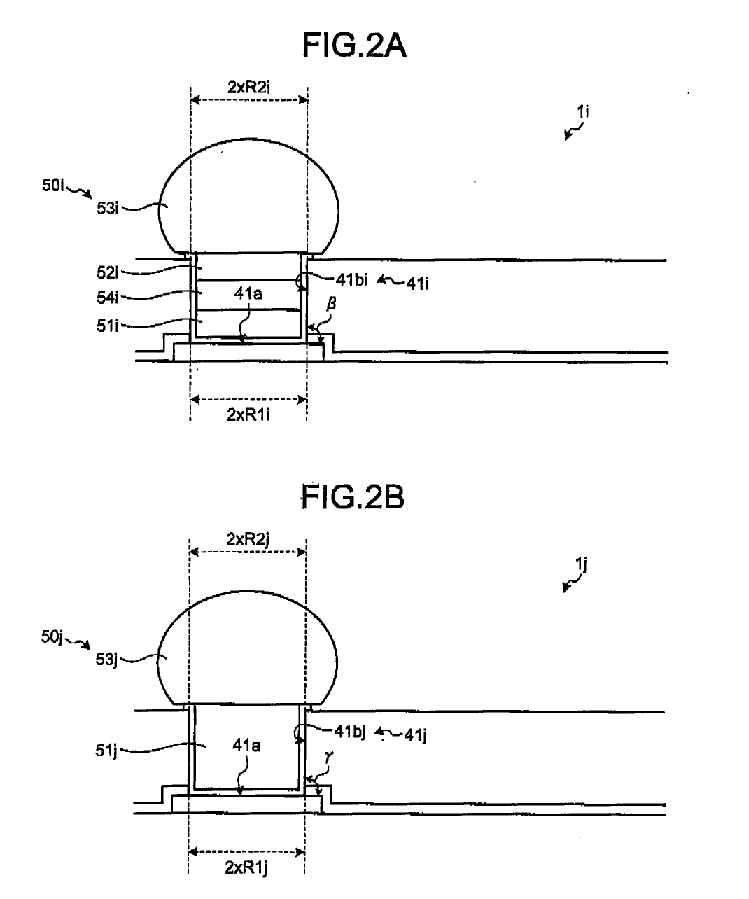

Furthermore, as shown in FIG. 2A, in a semiconductor device 1i, an opening 411 may have a columnar shape (for example, an approximately cylindrical shape) in which the width (2×R2i) of the upper part is approximately the same as the width (2×R1i) of the bottom surface. That is, a taper angle β of the side surface 41bi of the opening 41i with respect to the surface of the peripheral portion 22 covered by the buffer coat film 40 may be approximately 90°. With this configuration, even when the diameter of a micro-bump 50i is shrunk, the contact area between the micro-bump 50i and the buffer coat film 40 can be more easily made larger than the contact area between the micro-bump 50i and the electrode pad 20. Moreover, even when the diameter of the micro-bump 50i is shrunk, it is possible to prevent more effectively the micro-bump 50i from being tilted in the process of manufacturing the semiconductor device 1i.

In this case, the micro-bump 50i may have a configuration in which a layer (first layer) 51i, a layer (third layer) 54i, a layer (fourth layer) 52i, and a layer (second layer) 53i are sequentially stacked. For example, the layers 51i, 54i, and 52i constitute the lower part (the portion buried in the opening 41i) of the micro-bump 50i, and the layer 53i constitutes the upper part of the micro-bump 50i. The layer 51i covers the bottom surface 41a of the opening 41i. The layer 51i is formed, for example, of a metal containing copper as its main component. The layer 54i covers the layer 51i. The layer 54i is formed, for example, of a metal containing nickel as its main component. The layer 52i covers the layer 54i. The layer 521 is formed, for example, of a metal containing copper as its main component. The layer 53i covers the surfaces of the layer 51i and the buffer coat film 40 in the vicinity of the opening 41i. The layer 53i is formed, for example, of metal (for example, SnCu, SnAg, and SnAgCu) containing tin as its main component. By forming the micro-bump 50i so as to have such a layer configuration, even when the taper angle β of the side surface 41bi of the opening 41i is approximately 90°, it is possible to secure the property of the micro-bump 50i in the opening 41i during the manufacturing process.

Alternatively, as shown in FIG. 2B, in a semiconductor device 1j, an opening 41j may have a columnar shape (for example, an approximately cylindrical shape) in which the width (2×R2j) of the upper part is approximately the same as the width (2×R1j) of the bottom surface. That is, a taper angle γ of the side surface 41bj of the opening 41j with respect to the surface of the peripheral portion 22 covered by the buffer coat film 40 may be approximately 90°. With this configuration, even when the diameter of a micro-bump 50j is shrunk, the contact area between the micro-bump 50j and the buffer coat film 40 can be more easily made larger than the contact area between the micro-bump 50j and the electrode pad 20. Moreover, even when the diameter of the micro-bump 50j is shrunk, it is possible to prevent more effectively the micro-bump 50j from being tilted in the process of manufacturing the semiconductor device 1j.

In this case, the micro-bump 50j may have a configuration in which a layer (first layer) 51j and a layer (second layer) 53j are sequentially stacked. For example, the layer 51j constitutes the lower part (the portion buried in the opening 41j) of the micro-bump 50j, and the layer 53j constitutes the upper part of the micro-bump 50j. The layer 51j covers the bottom surface 41a of the opening 41j. The layer 51j is formed, for example, of a metal containing copper as its main component. The layer 53j covers the surfaces of the layer 51j and the buffer coat film 40 in the vicinity of the opening 41j. The layer 53j is formed, for example, of metal (for example, SnCu, SnAg, and SnAgCu) containing tin as its main component. By forming the micro-bump 50j so as to have such a layer configuration, even when the taper angle γ of the side surface 41bj of the opening 41j is approximately 90°, it is possible to secure the property of the micro-bump 50j in the opening 41j during the manufacturing process.

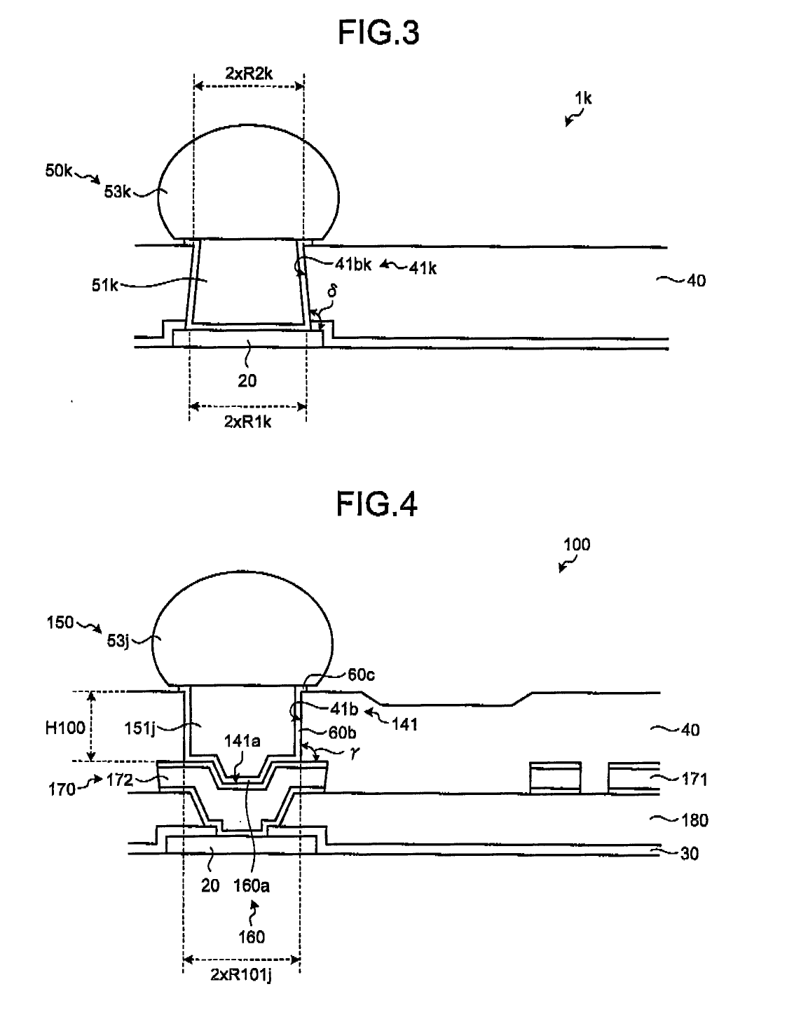

Alternatively, as shown in FIG. 3, in a semiconductor device 1k, an opening 41k may have an inverted-tapered shape in which the width (2×R2k) of the upper part is smaller than the width (2×R1k) of the bottom surface. That is, a taper angle δ of a side surface 41bk of the opening 41k with respect to the surface of the peripheral portion 22 covered by the buffer coat film 40 may be approximately 90° (that is, an angle slightly larger than 90°). With this configuration, since the buffer coat film 40 can hold the micro-bump 50k while resisting against the stress that pulls the micro-bump 50k from the electrode pad 20, it is possible to further improve the force of attaching the micro-bump 50k to the semiconductor element 2. Moreover, in the case of the bumps tapered at the bottom, since it can be formed by a bottom-up process using plating-precipitation with additives, there is no problem in forming such a shape.

Moreover, even when the diameter of the micro-bump 50k is shrunk, the contact area between the micro-bump 50k and the buffer coat film 40 can be easily made larger than the contact area between the micro-bump 50k and the electrode pad 20. Moreover, even when the diameter of the micro-bump 50k is shrunk, it is possible to prevent the micro-bump 50k from being tilted in the process of manufacturing the semiconductor device 1k.

### Second Embodiment

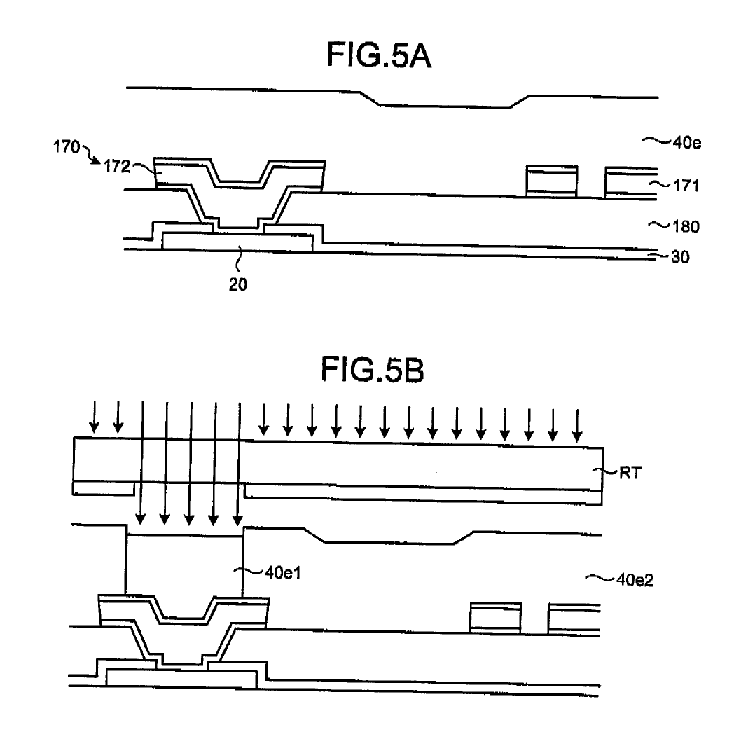

Next, a semiconductor device 100 according to a second embodiment will be described with reference to FIG. 4. FIG. 4 is a diagram showing a configuration of the semiconductor device 100 in the vicinity of a micro-bump 150. In the following description, portions different from those of the first embodiment will be mainly described.

The semiconductor device 100 includes a buffer coat film 180, a redistribution layer 170, and the micro-bump 150.

The buffer coat film 180 covers the peripheral portion 22 of the electrode pad 20, the semiconductor element 2, and the passivation film 30. The buffer coat film 180 may be formed of the same material as the buffer coat film 40 and may be formed of a material different from that of the buffer coat film 40. The buffer coat film 180 is formed, for example, of a phenolic resin or a polyimide resin.

The redistribution layer 170 is disposed on the buffer coat film 180. The redistribution layer 170 includes a pattern 171 that transfers signals between predetermined electrode pad and a pattern 172 that connects the electrode pad 20 and the micro-bump 150. The redistribution layer 170 is formed of a predetermined metal. The redistribution layer 170 is formed, for example, of a three-layer plating film made up of a titanium metal layer, a copper metal layer, and a nickel metal layer.

The pattern 172 is connected to the electrode pad 20 through a first opening which has a first width smaller than the diameter (2×R101j) of the bottom surface of the micro-bump 150 and a second opening which has a second width smaller than the diameter (2×R101j) of the bottom surface of the micro-bump 150 and larger than the first width. With this configuration, the surface of the pattern 172 has an irregularity corresponding to the first and second opening. That is, a bottom surface 141a of an opening 141 has an irregularity corresponding to the first and second opening.

The micro-bump 150 has similar configuration to the micro-bump 50k shown in FIG. 3, for example, but is different from the micro-bump 50k shown in FIG. 3 in that an irregularity corresponding to the bottom surface 141a of the opening 141 is formed on the bottom surface thereof. The micro-bump 150 may have similar shape to the micro-bump 50 shown in FIG. 1B, the micro-bump 50i shown in FIG. 2A, or the micro-bump 50j shown in FIG. 2B, for example.

The second embodiment is similar to the first embodiment in that the contact area ‘Sb’ between the micro-bump 150 and the side surfaces 41b of the opening 141 is larger than the contact area ‘Sa’ between the micro-bump 150 and the bottom surface 141a of the opening 141. Therefore, according to the second embodiment, even when the contact area between the micro-bump 150 and the electrode pad 20 (with the pattern 171 disposed therebetween) decreases as the diameter of the micro-bump 150 is shrunk, it is possible to secure the force of closely attaching the micro-bump 150 to the buffer coat film 180. As a result, it is possible to improve the force of attaching the micro-bump 150 to the semiconductor element 2.

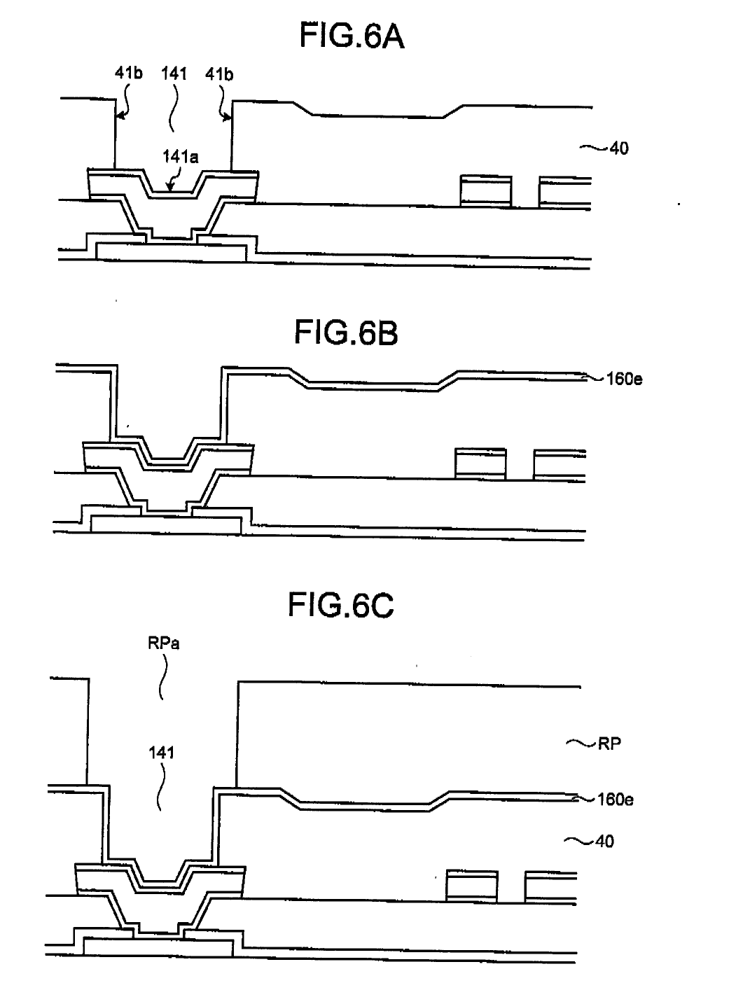

Next, a method for manufacturing the semiconductor device 100 according to the second embodiment will be described with reference to FIGS. 5A to 7C. FIGS. 5A to 7C are cross-sectional diagrams showing the processes of the method for manufacturing the semiconductor device 100. The manufacturing method described below can be equally applied to a method for manufacturing the semiconductor device 1 according to the first embodiment by adding changes corresponding to structural differences.

In a process shown in FIG. 5A, the pattern of the electrode pad 20 is formed on the semiconductor element 2, for example, using metal containing aluminum as its main component. Subsequently, a passivation film is formed so as to cover the semiconductor element 2 and the electrode pad 20, for example, using a polyimide resin. Subsequently, a buffer coat film is formed so as to cover the semiconductor element 2, the electrode pad 20, and the passivation film, for example, using a phenolic resin or a polyimide resin. Moreover, the first and second opening in which the pattern 172 is buried are formed on the passivation film 30 and the buffer coat film 180.

After that, a conductive layer which serves as the pattern 172 is deposited on the entire surface and patterned, whereby the patterns 171 and 172 of the redistribution layer 170 are formed. The redistribution layer 170 is formed of predetermined metal, and for example, is formed of a three-layer plating film made up of a titanium metal layer, a copper metal layer, and a nickel metal layer. Subsequently, a buffer coat film 40e is deposited on the entire surface so as to cover the buffer coat film 180 and the redistribution layer 170. The buffer coat film 40e is formed, for example, of a phenolic resin or a polyimide resin.

In a process shown in FIG. 5B, an exposure treatment is performed using a reticle RT so as to selectively expose a predetermined region 40e1 without exposing the peripheral region 40e2 of the buffer coat film 40e. In this way, a latent image of the region 40e1 is formed on the buffer coat film 40e.

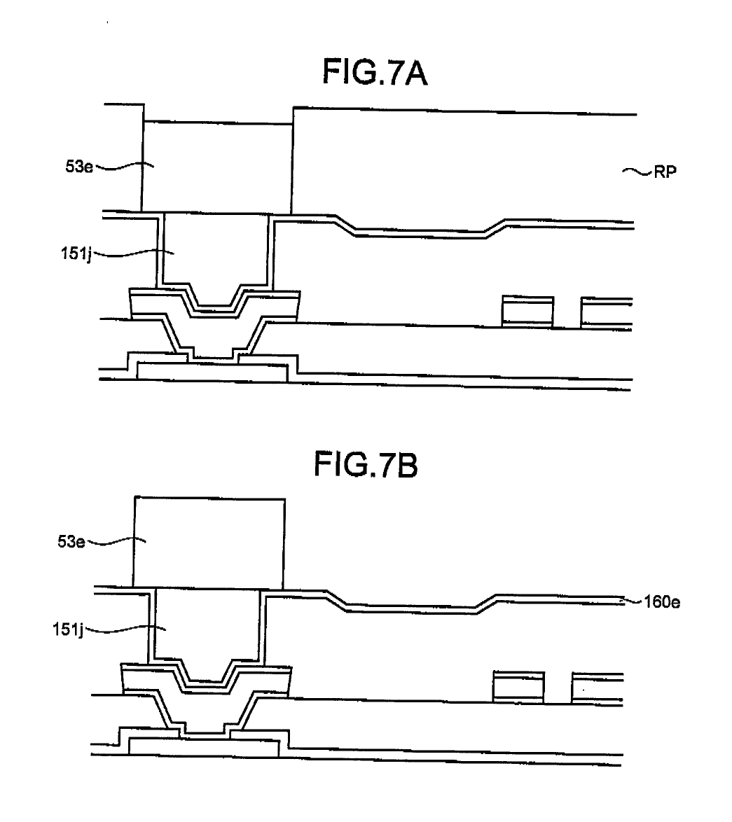

In a process shown in FIG. 6A, the latent image of the region 40e1 in the buffer coat film 40e is developed using a predetermined developing solution. In this way, opening 141 are formed on the buffer coat film 40. The opening 141 have a configuration such that the area of the side surfaces 41b is larger than the area of the bottom surface 141a.

In a process shown in FIG. 6B, a conducting layer 160e is deposited so as to cover the bottom surface 141a and the side surfaces 41b of the opening 141. The conducting layer 160e is formed, for example, of a metal containing copper as its main component.

In a process shown in FIG. 6C, a resist pattern RP having an opening pattern RPa corresponding to the opening 141 is formed on the buffer coat film 40 and the conducting layer 160e. The opening pattern RPa is a pattern which includes the opening 141 when seen in a direction perpendicular to the surface of the electrode pad 20 and has a width corresponding to the maximum width (2×R3; see FIG. 1B) of the micro-bump.

In a process shown in FIG. 7A, metal containing copper as its main component is buried in the opening 141 by a plating treatment. In this way, a layer 151j which serves as the lower part of the micro-bump 150 is formed. Moreover, metal (for example, SnCu, SnAg, and SnAgCu) containing tin as its main component is buried in the opening pattern RPa by a plating treatment. In this way, a layer 53e which serves as the upper part of the micro-bump 150 is formed.

In a process shown in FIG. 7B, the resist pattern RP is selectively removed.

In a process shown in FIG. 7C, the exposed portion of the conducting layer 160e is selectively removed by dry-etching or the like using the pattern of the layer 53e as a mask. In this way, formed is the conducting layer 160 which has a bottom surface portion 160a covering the bottom surface 141a of the opening 141, side surface portions 60b covering the side surfaces 41b of the opening 141, and end portions 60c covering the end portions on the surface of the buffer coat film 40 being in contact with the opening 141. In this case, since side-etching may occur so that the lower side of the layer 53e is unnecessarily etched, a clearance CL disposed between the lower end of the layer 53e and the surface of the buffer coat film 40 is formed outside the end portions 60c.

A reflow treatment is performed on the layer 53e at a predetermined temperature, whereby a layer 53j having a rounded shape is formed. In this way, the micro-bump 150 in which the layers 151j and 53j are sequentially stacked and alloyed is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their-equivalents are intended to cover such forms or modifications as would fall within the scope and spirit of the inventions.

What is claimed is:

1. A semiconductor device comprising:
a semiconductor element;
an electrode pad of the semiconductor element;
a buffer coat film having an opening corresponding to the electrode pad; and
a micro-bump electrically connected to the electrode pad through the opening,
wherein a contact area between the micro-bump and side surfaces of the opening is larger than a contact area between the micro-bump and a bottom surface of the opening.

2. The semiconductor device according to claim 1,
wherein the micro-bump includes:
a lower part buried in the opening; and
an upper part disposed above the opening,
wherein a contact area between the lower part of the micro-bump and the side surfaces of the opening is larger than a contact area between the lower part of the micro-bump and the bottom surface of the opening.

3. The semiconductor device according to claim 1,
wherein the contact area between the micro-bump and the side surfaces of the opening is more than twice as large as the contact area between the micro-bump and the bottom surface of the opening.

4. The semiconductor device according to claim 1,
wherein the micro-bump includes:
a lower part buried in the opening; and
an upper part disposed above the opening,
wherein a contact area between the lower part of the micro-bump and the side surfaces of the opening is more than twice as large as a contact area between the lower part of the micro-bump and the bottom surface of the opening.

5. The semiconductor device according to claim 1,
wherein a taper angle of the side surface of the opening is equal to or larger than 80°.

6. The semiconductor device according to claim 1,
wherein the opening has a forward-tapered shape in which a width of the upper part is larger than a width of the bottom surface.

7. The semiconductor device according to claim 5,
wherein the taper angle is equal to or larger than 90°.

8. The semiconductor device according to claim 7,
wherein the opening has a columnar shape in which a width of the upper part is approximately the same as a width of the bottom surface.

9. The semiconductor device according to claim 7,
wherein the opening has an inverted-tapered shape in which a width of the upper part is smaller than a width of the bottom surface.

10. The semiconductor device according to claim 6,
wherein the micro-bump includes:
a first layer which covers the bottom surface of the opening and which is formed of a material containing copper as its main component;
a fourth layer which is disposed on the first layer and which is formed of a material containing copper as its main component; and
a second layer which is disposed on the fourth layer and which is formed of a material containing tin as its main component.

11. The semiconductor device according to claim 10,
wherein, in the micro-bump, the first and fourth layers are buried in the opening, and the second layer is disposed above the opening.

12. The semiconductor device according to claim B,
wherein the micro-bump includes:
a first layer which covers the bottom surface of the opening and which is formed of a material containing copper as its main component; and
a second layer which is disposed on the first layer and which is formed of a material containing tin as its main component.

13. The semiconductor device according to claim 12,
wherein, in the micro-bump, the first layer is buried in the opening, and the second layer is disposed above the opening.

14. The semiconductor device according to claim 12,
wherein the micro-bump further includes:
a third layer which is disposed between the first layer and the second layer and which is formed of a material containing nickel as its main component; and
a fourth layer which is disposed between the third layer and the second layer and which is formed of a material containing copper as its main component.

15. The semiconductor device according to claim 14,
wherein, in the micro-bump, the first, third, and fourth layers are buried in the opening, and the second layer is disposed above the opening.

16. The semiconductor device according to claim 9,
wherein the micro-bump includes:
a first layer which covers the bottom surface of the opening and which is formed of a material containing copper as its main component; and
a second layer which is disposed on the first layer and which is formed of a material containing tin as its main component.

17. The semiconductor device according to claim 16,
wherein, in the micro-bump, the first layer is buried in the opening, and the second layer is disposed above the opening.

18. The semiconductor device according to claim 1, further comprising a conducting layer disposed between the micro-bump and the opening.

19. The semiconductor device according to claim 18,
wherein the micro-bump includes:
a lower part buried in the opening; and
an upper part disposed above the opening,
wherein the conducting layer connects a bottom surface of the opening to a bottom surface of the lower part of the micro-bump and connects side surfaces of the opening to side surfaces of the lower part of the micro-bump.

20. The semiconductor device according to claim 18, further comprising a pattern of a redistribution layer which is disposed between the conducting layer and the opening.
